(19) United States
(12) Patent Application Publication
(10) Pub. No.: US 2008/0189107 A1
(43) Pub. Date: Aug. 7, 2008

(54) Estimating own-voice activity in a hearing-instrument system from direct-to-reverberant ratio

(75) Inventor: Soren Laugesen, Smorum (DK)

Correspondence Address: BIRCH STEWART KOLASCH & BIRCH, PO BOX 747, FALLS CHURCH, VA, 22040-0747, US

(73) Assignee: Oticon A/S, Smorum (DK)

(21) Appl. No.: 11/878,275

(22) Filed: Jul. 23, 2007

(30) Foreign Application Priority Data
Feb. 6, 2007 (EP) 07 101 796.6

(51) Int. Cl. G10L 15/00; H03G 3/00

(52) U.S. Cl. 704/233; 381/63

(57) ABSTRACT

A method of identifying the user's own voice in a hearing instrument system and a hearing instrument system for performing such method is provided wherein a direct-to-reverberant ratio (DtoR) between the signal energy of a direct sound part (1a; 1b) and that of a reverberant sound part (2a, 3a; 2b, 3b) of at least a part of a recorded sound is used to assess wether the sound originates from the users own voice or not. This allows a very reliable detection of the users own voice in a hearing-instrument system. Further, a hearing-instrument system comprising an own-voice detector configured to perform such method is provided.

### FIELD OF INVENTION

This invention relates to a hearing-instrument system comprising an own-voice detector and to the method of identifying the user's own voice in a hearing-instrument system. In this context a hearing-instrument may be hearing aids, such as an in-the-ear (ITE), completely-in-canal (CIC) or behind-the-ear (BTE) hearing aids, headphones, headsets, hearing protective gear, intelligent earplugs etc.

### BACKGROUND OF INVENTION

The most common complaint about hearing aids, especially when someone starts wearing them for the first time, is that the sound of their own voice is to loud or that it sounds like they are talking into a barrel. Accordingly, there exists the need to identify the own voice of the user of a hearing aid to be able to process the users own voice in a different way than sound originating from other sound sources.

In prior art document WO 2004/077090 A1 there are described different methods for distinguishing between sound from the users mouth and sound originating from other sources. The methods described in WO 2004/077090 A1 have the drawback that the signals from two or more microphones are needed for the identification of the user's own voice.

Other known methods for identifying the user's own voice in a hearing aid, which are based on a quantity derived from a single microphone signal, are e.g. based on overall level, pitch, spectral shape, spectral comparison of auto-correlation and auto-correlation of predictor coefficients, cepstral coefficients, prosodic features or modulation metrics. It has not been demonstrated or even theoretically substantiated that these methods will perform reliable own-voice detection.

Another known method for identifying the user's own voice is based on the input from a special transducer, which picks up vibrations in the ear canal caused by vocal activity. While this method of own-voice detection is expected to be very reliable, it requires a special transducer, which is expected to be difficult to realize and costly.

The object of this invention is to provide a method of identifying the users own voice in a hearing-instrument system and a hearing-instrument system comprising an own-voice detector, which provides reliable and simple detection of the user's own voice.

### SUMMARY OF THE INVENTION

The object of the invention is solved by a method according to claim 1 and by a hearing-instrument system according to claim 8. Further developments are characterized in the dependent claims.

In the method of identifying the user's own voice in a hearing-instrument system according to the invention, assessing whether the sound originates from the user's own voice or from another sound source is based on the direct-to-reverberant ratio (DtoR) between the signal energy of a direct sound part and that of a reverberant sound part of at least a part of a recorded sound. This method has the advantage that the direct-to-reverberant ratio (DtoR) allows very reliable detection of the user's own voice.

In accordance with a preferred embodiment of the invention, it is possible with this method to identify the user's own voice on the basis of the signal from one microphone as the direct-to-reverberant ratio (DtoR) is determined from the envelope of the signal energy.

From the direct-to-reverberant ratio (DtoR), it can be assessed whether the sound originates from a near-field sound source (the user's own voice) or from a far-field sound source by comparing the direct-to-reverberant ratio to an own-voice threshold value which can be determined empirically from experiments made in advance.

An even more reliable method for detecting the users own voice in a hearing-instrument system can be realized by independently determining the direct-to-reverberant ratio in a number of frequency bands and assessing whether the sound originates from the user's own voice on the basis of the direct-to-reverberant ratios of the number of frequency bands.

If assessing whether the sound originates from the user's own voice is based on a combination of the direct-to-reverberant ratio (DtoR) and another characteristic of the recorded sound, then there is the advantage that the own-voice detection will be more robust compared to the case in which detection is based only on the direct-to-reverberant ratio.

### BRIEF DESCRIPTION OF THE DRAWINGS

The invention will be more easily understood by the person skilled in the art from the following description of preferred embodiments in connection with the drawings. In the figures thereof:

FIG. 1 shows the typical appearance of a reflectogram of a reverberant acoustical environment, when the source and the receiver are spaced a few meters apart;

FIG. 2 shows the typical appearance of a reflectogram of a reverberant acoustical environment, when the source and the receiver are close together;

FIG. 3 is the flow diagram of a preferred embodiment of a method of identifying the user's own voice in a hearing-instrument system according to the invention; and

FIG. 4 is a schematic block diagram of a preferred embodiment of a hearing instrument system according to the invention.

### DETAILED DESCRIPTION OF PREFERRED EMBODIMENTS

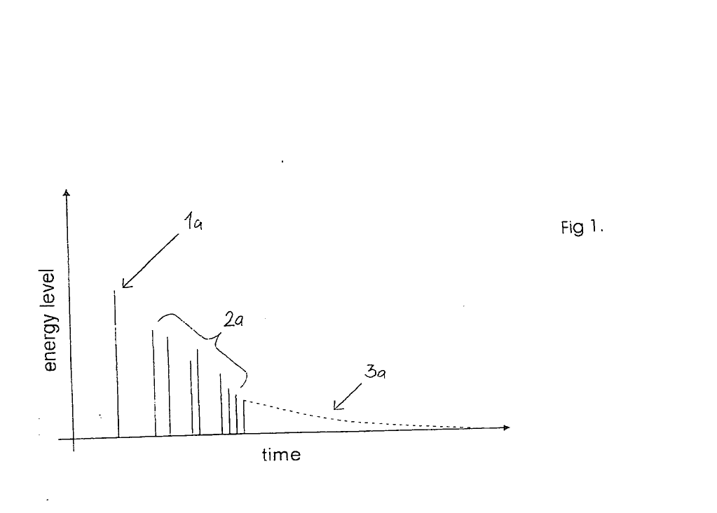

In FIG. 1, there is shown the reflectogram of an acoustic environment in which there are reflective surfaces present. The so called direct-to-reverberant ratio (DtoR) between the energy level of the direct sound 1a and that of the reverberant tail comprising the early reflections 2a and the late reverberation 3a is typical for a situation where the sound source and the sound receiver are spaced apart by a few meters. This would be the case if the receiver is a hearing-instrument microphone and the source is a speaking-partner's voice.

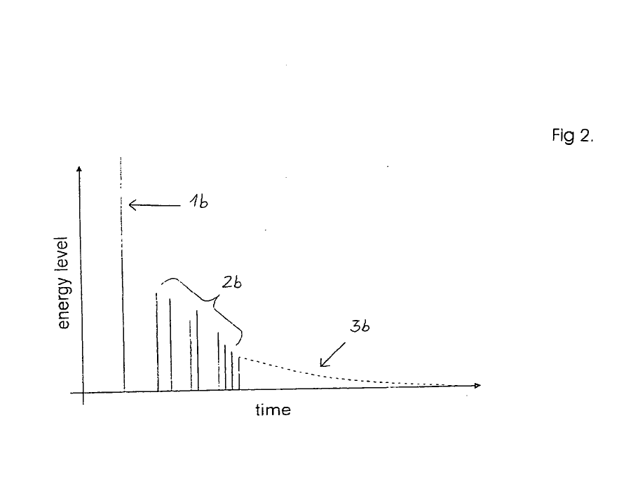

FIG. 2 shows the case wherein the sound source is the hearing-instrument wearer's own voice. Reference sign 1b designates the direct sound, reference sign 2b designates the early reflections and reference sign 3b designates the late reverberation. It is apparent that the direct-to-reverberant ratio (DtoR) is fundamentally different to that in the case of FIG. 1 wherein the sound source and the sound receiver are spaced apart by a few meters. The direct-to-reverberant ratio (DtoR) for the case of FIG. 2 is much higher than that for the case of FIG. 1.

The method of identifying the user's own voice in a hearing instrument system is based on the finding that the direct-to-reverberant ratio (DtoR) of a sound signal is higher if the sound originates from a near-field source—such as the user's own voice—than if the sound originates from a far-field sound source.

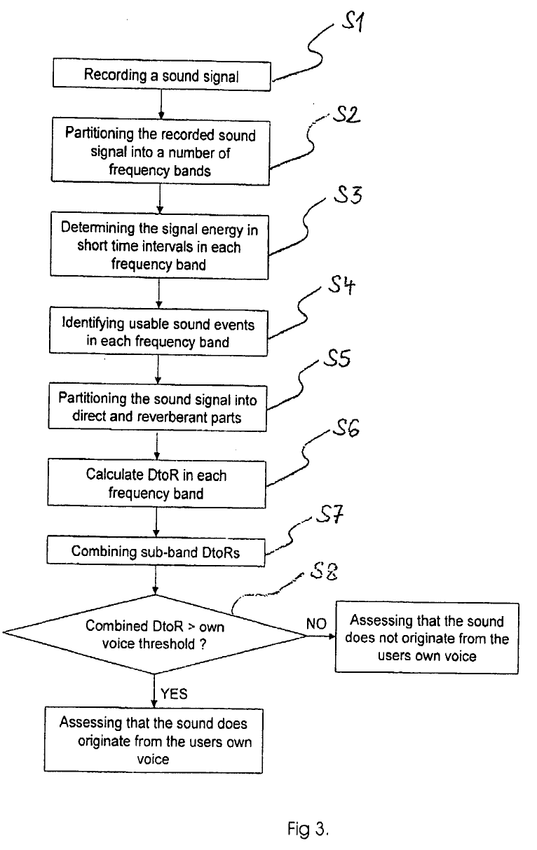

FIG. 3 shows the basic method steps of the method of identifying the user's own voice in a hearing-instrument system according to a preferred embodiment of the present invention.

In a first step S1, a sound signal is recorded. In a next step S2, this recorded sound signal is partitioned into a number of frequency bands. In a third step S3, the signal energy is determined in short time intervals, e.g. 20 ms, in each frequency band to obtain the envelope of the signal energy. In a fourth step S4, usable sound events are identified in each frequency band, which allow a reliable estimation of the direct-to-reverberant ratio (DtoR). This is accomplished by examining the determined envelopes in successive segments of, for example, 700 ms. Thus, it is examined whether or not each successive segment comprises a sufficiently sharp onset (corresponding to the direct sound 1a, 2a) and an approximately exponentially decaying tail of sufficient duration (corresponding to the reverberant sound 1b, 1c, 2b, 2c). Accordingly, the identified usable sound events comprise a direct sound part and a reverberant sound part. In step S5, the sound events identified in step S4 are partitioned into direct and reverberant sound parts in each frequency band. In step S6, a direct-to-reverberant ratio (DtoR) between the signal energy of the direct sound part (1a; 1b) and that of the reverberant sound part (2a 3a; 2b, 3b) is calculated in each frequency band. Then, in a next step S7, all the individual direct-to-reverberant ratios (DtoR) of the different frequency bands are combined into a single final direct-to-reverberant ratio (combined direct-to-reverberant ratio). Therein the combined direct-to-reverberant ratio can be the average of the sub-band direct-to-reverberant ratios, for example. In step S8, this combined direct-to-reverberant ratio is compared with an own-voice threshold, wherein this own-voice threshold is determined empirically in experiments. If the combined direct-to-reverberant ratio is above the own-voice threshold then it is decided that the recorded sound signal is of the user's own voice. Otherwise it is decided that the recorded sound signal is not of the user's own voice.

If it is decided that the recorded sound signal is of the user's own voice, separate and dedicated signal processing can be activated in the hearing instrument before outputting the processed sound to the user.

In a modified embodiment, the method of identifying the user's own voice may be combined with the output of other own-voice detectors to obtain a final own-voice detector output which is more robust. The combination with other own-voice detectors can be done in such way that a flag is set for each own-voice detector assessing that the recorded sound signal is of the user's own voice. In this case, the final own-voice detector output determines that the recorded sound signal is the user's own voice if a predetermined number of flags is set. Due to the fact that the determination of the direct-to-reverberant ratio (DtoR) from the envelope of the signal energy involves a latency in the order of one second, it is preferable to combine the present invention with other faster own-voice detectors known in the prior art. In this way, the reliability of the own-voice detection based on the direct-to-reverberant ratio can be combined with the high speed of detection by other less reliable methods.

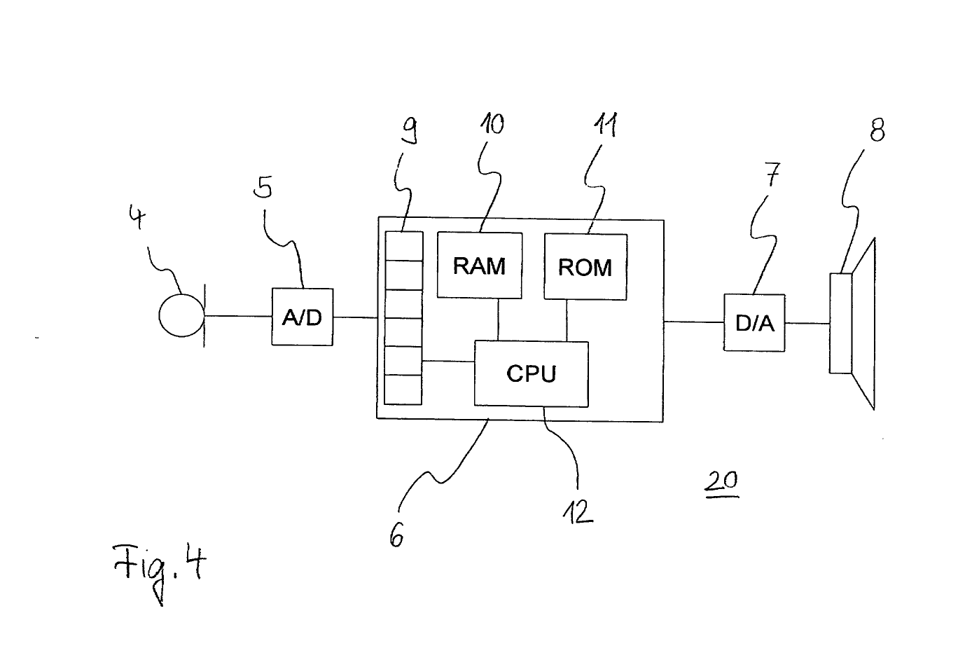

In the following, a hearing instrument system for performing the above described method is described with reference to FIG. 4.

A hearing-instrument system 20 which can perform the above described method comprises a microphone 4, an A/D converter 5 connected to the microphone 4, a digital signal processing unit 6, the input of which is connected to the output of the A/D converter 5, a D/A converter 7, the input of which is connected to the output of the digital signal processing unit 6, and a loudspeaker 8 which is connected to the output of the D/A converter 7. The digital signal processing unit 6 includes a filter bank 9, a random access memory (RAM) 10, a read-only-memory (ROM) 11 and a central processing unit (CPU) 12.

The microphone 4 is means for recording a sound signal, the filter bank 9 is means for partitioning the recorded sound signal into a number of frequency bands and the CPU 12, the RAM 10 and the ROM 11 are means for determining the signal energy in short time intervals, for identifying usable sound events, for partitioning the sound events into direct and reverberant parts (1a, 2a, 3a; 1b, 2b, 3b), for calculating the direct-to-reverberant ratio (DtoR) in each frequency band and for combining the sub-band direct-to-reverberant ratios to a final combined direct-to-reverberant ratio as well as for comparing the combined direct-to-reverberant ratio (combined DtoR) with an own-voice threshold to decide whether or not the recorded sound signal originates from the user's own voice.

The hearing-instrument system may be hearing aids, such as an in-the-ear (ITE), completely-in-canal (CIC), behind-the-ear (BTE), or a receiver-in-the-ear (RITE) hearing aid.

Modifications from the above described preferred embodiments of the invention are possible. For example, it is described to partition a recorded sound signal into a number of frequency bands and to calculate a direct-to-reverberant ratio (DtoR) in each frequency band. However, it is also possible to realize the own voice detection of the invention in only one single broad frequency band. The before described hearing-instrument system uses digital signal processing. However, it is also possible to use analogue processing of the sound signals.

1. Method of identifying the user's own voice in a hearing-instrument system (20), characterized by the steps:
determining a direct-to-reverberant ratio (DtoR) between the signal energy of a direct sound part and that of a reverberant sound part of at least a part of a recorded sound;
and assessing whether the sound originates from the user's own voice on the basis of the direct-to-reverberant ratio.

2. Method in accordance with claim 1 characterized in that the step of assessing whether the sound originates from the user's own voice includes the steps of:
comparing the direct-to-reverberant ratio to an own-voice threshold value and
assessing that the recorded sound originates from the user's own voice if the direct-to-reverberant ratio is above the own-voice threshold value.

3. Method in accordance with claim 1 characterized in that the method further comprises the step of partitioning the recorded sound into a number of frequency bands;
the direct-to-reverberant ratio between the signal energy of the direct sound part and that of the reverberant sound part is determined for each of the number of frequency bands; and
it is assessed whether the recorded sound originates from the user's own voice on the basis of the direct-to-reverberant ratios of the number of frequency band.

4. Method in accordance with claim 3 characterized in that the step of assessing whether the sound originates from the user's voice includes the following steps:
combining the direct-to-reverberant ratios determined for each of the number of frequency bands to obtain a combined direct-to-reverberant ratio;
comparing the combined direct-to-reverberant ratio to an own-voice threshold value; and
assessing that the recorded sound originates from the user's own voice if the combined direct-to-reverberant ratio is above an own-voice threshold.

5. Method in accordance with one of claims 1 to 4 characterized in that determining the direct-to-reverberant ratio (DtoR) includes the following steps:
determining the sound signal energy in short time intervals to obtain the envelope of the signal energy in these intervals;
calculating the direct-to-reverberant ratio from the envelope of the signal energy in these intervals.

6. Method in accordance with claim 1 characterized in that assessing that the sound originates from the user's own voice is based on a combination of the direct-to-reverberant ratio (DtoR) and another characteristic of the recorded sound.

7. Method in accordance with claim 1 characterised in that the method further comprises the step of identifying a sound event in the recorded sound that allows a reliable estimation of the direct-to-reverberant ratio (DtoR).

8. Hearing-instrument system comprising an own voice detector characterized in that the own voice detector includes:
determining means for determining a direct-to-reverberant ratio (DtoR) between the signal energy of a direct sound part and that of a reverberant sound part of at least a part of a recorded sound; and
assessing means for assessing whether the recorded sound originates from the user's own voice on the basis of the direct-to-reverberant ratio (DtoR).

9. Hearing-instrument system in accordance with claim 8 characterized in that the assessing means are configured to compare the direct-to-reverberant ratio (DtoR) with an own-voice threshold value and to assess that the recorded sound originates from the user's own voice if the direct-to-reverberant ratio (DtoR) is above the own-voice threshold value.

10. Hearing-instrument system in accordance with claim 8 characterized in that
the hearing-instrument system further comprises partitioning means for separating the sound event into different frequency bands;
the determining means determines the direct-to-reverberant ratio (DtoR) in each frequency band; and
the assessing means assesses whether the recorded sound event originates from the user's own voice on the basis of the direct-to-reverberant ratios in each frequency band.

11. Hearing-instrument system in accordance with claim 10 characterized in that the assessing means are configured for combining the direct-to-reverberant ratios (DtoR) determined for each of the number of frequency bands to obtain a combined direct-to-reverberant ratio (DtoR), comparing the combined direct-to-reverberant ratio (DtoR) to an own-voice threshold value; and assessing that the recorded sound originates from the user's own voice if the combined direct-to-reverberant ratio (DtoR) is above an own-voice threshold.

12. Hearing-instrument system in accordance with one of claims 8 to 11 characterized by combining means combining the output of the assessing means with the output of other own-voice detectors to obtain a more robust decision about whether the recorded sound originates from the user's own voice or not.

13. Hearing-instrument system in accordance with claim 8 characterized in that the determining means is configured for determining the sound signal energy in short time intervals to obtain envelope of the signal energy in these intervals and for calculating the direct-to-reverberant ratio (DtoR) from the envelope of the signal energy in these intervals.

14. Hearing-instrument system in accordance with claim 7 characterized by further comprising identification means for identifying a sound event in the recorded sound that allows a reliable estimation of the direct-to-reverberant ratio (DtoR).
